(19) United States
(12) Patent Application Publication
(10) Pub. No.: US 2025/0232966 A1
(43) Pub. Date: Jul. 17, 2025

(54) WAFER PROCESSING APPARATUS

(71) Applicant: HITACHI HIGH-TECH CORPORATION, Minato-ku, Tokyo (JP)

(72) Inventors: Yutaka KADOMOTO, Tokyo (JP); Kohei SATO, Tokyo (JP)

(21) Appl. No.: 18/691,276

(22) PCT Filed: Mar. 29, 2023
(86) PCT No.: PCT/JP2023/012810

§ 371 Date: Mar. 12, 2024

(51) Int. Cl. H01J 37/32; B01D 53/34; B01D 53/38; B01D 53/76; H01L 21/67

(52) U.S. Cl. CPC H01J 37/32844; B01D 53/346; B01D 53/38; B01D 53/76; B01D 2258/0216; H01J 37/32678; H01J 2237/334; H01L 21/67017

(57) ABSTRACT

To provide a wafer processing apparatus that can appropriately reduce impact gases in the exhaust gas by a scrubber. A wafer processing apparatus includes: a wafer processing unit that supplies a treatment gas to a vessel and processes a wafer that is placed in the vessel as a processed target, and the wafer processing unit being joined to a scrubber that performs a scrubbing process to reduce an impact gas in an exhaust gas discharged from the vessel; and a control device that controls the wafer processing unit and the scrubber. The scrubber is equipped with the function to increase or decrease the amount of the impact gas reduced by the scrubbing process based on the received command signals or signals indicating different amounts of impact gases. The control device transmits beforehand scrubbing operation information for the scrubber, the scrubbing operation information changing an operating state of the scrubber to enable the scrubbing process of the exhaust gas based on a processing condition of the wafer in the wafer processing unit obtained in advance.

### TECHNICAL FIELD

The present disclosure relates to a wafer processing apparatus equipped with at least one or more wafer treaters that process, in a processing chamber, a sample in a substrate shape such as a semiconductor wafer placed in the processing chamber in a vessel. More specifically, the present disclosure relates to a wafer processing apparatus connected to a scrubber having a function that reduces a predetermined gas contained in an exhaust gas emitted from a wafer treater and having a large impact to an environment.

### BACKGROUND ART

As a representative example of wafer processing apparatuses that process semiconductor wafers, there is a semiconductor fabrication apparatus that fabricates semiconductor devices (elements), for example. As a semiconductor fabrication apparatus, there is a semiconductor fabrication apparatus having at least one or more wafer treaters that process semiconductor wafers.

Each wafer treater includes a vessel with a processing chamber in which a semiconductor wafer is placed. In each wafer treater, treatment gases are supplied to the semiconductor wafer in the processing chamber, and these gases are excited or dissociated into plasma or similar states, utilizing physical or chemical reactions to form a film layer as a processed target pre-formed on the semiconductor wafer into a predetermined shape.

In such wafer processing apparatuses, including semiconductor fabrication apparatus, multiple types of gases suitable for processing film layers as a processed target are used. The gases used in the processing are exhausted outside the vessel by an exhaust system and finally discharged outside the building in which the wafer processing apparatus is installed.

However, the exhaust gas discharged from the wafer processing apparatus may contain particular gases that have a high impact on the environment and people or that are harmful. In the following, these particular gases including gases that have a high impact on the environment and people and that are harmful are also referred to as “impact gases.”

Therefore, it has been considered that a scrubber equipped with a function to reduce or remove impact gases contained in the exhaust gas is connected to the wafer processing apparatus. Consequently, the impact gases included in the exhaust gas discharged from the wafer processing apparatus are reduced or removed by the scrubber before being discharged outside the building.

As for the technology of scrubbers connected to wafer processing apparatuses, for example, a scrubber described in Japanese Unexamined Patent Application Publication No. 2016-080226 (Patent Literature 1) is known, Patent Literature 1 describes a technology in which exhaust gas is combusted using a combustible fuel in an internal combustion chamber, heated, and thermally decomposed to render the gas harmless. Additionally, Japanese Unexamined Patent Application Publication No. 2003-120918 (Patent Literature 2) discloses a technology in which gas for burning (combustion gas) used for burning a treatment gas as a scrubbing target is supplied to a scrubber according to the amount of the treatment gas.

### CITATION LIST

### Patent Literature

Japanese Unexamined Patent Application Publication No. 2016-080226
Japanese Unexamined Patent Application Publication No. 2003-120918

### SUMMARY OF INVENTION

### Technical Problem

In processing semiconductor wafers during semiconductor fabrication, multiple processing steps are carried out in one wafer processing apparatus. Generally, the type and amount of gas used vary according to the processing conditions in each process. Therefore, it is desirable for the scrubber to be able to sufficiently reduce the impact gases in the exhaust gas, which vary in type and amount according to time, date, and so on.

However, Patent Literature 1 does not describe the operation of the scrubber according to fluctuations in the amount of exhaust gas supplied to the scrubber. Moreover, although Patent Literature 2 describes adjusting the supply amount of combustion gas according to the flow rate of the exhaust gas, which is the treatment gas, Patent Literature 2 describes no scheme for adjusting the operation of the scrubber to sufficiently reduce the impact gases, even when the type and amount of impact gases in the exhaust gas change.

Therefore, the technologies described in Patent Literatures 1 and 2 may not be sufficient to detoxify the impact gases when the amount of impact gases fluctuates as different processes with various conditions are repeatedly carried out in each of the multiple wafer treaters over time.

Furthermore, it can be considered to solve the above problem by continuously applying a high amount of thermal energy for sufficiently detoxifying the maximum amount of impact gases expected to be used in the wafer processing to the exhaust gas over a certain period and then to burn the impact gases. However, in this case, constantly applying a high amount of thermal energy during the specified period to burn the impact gases may increase the operating costs of the wafer processing apparatus.

An object of the present disclosure is to provide a wafer processing apparatus that can appropriately reduce impact gases in the exhaust gas by a scrubber.

### Solution to Problem

A wafer processing apparatus of the present disclosure includes a wafer processing unit that supplies a treatment gas to a vessel and processes a wafer that is placed in the vessel as a processed target, and the wafer processing unit being joined to a scrubber that performs a scrubbing process to reduce an impact gas in an exhaust gas discharged from the vessel, and a control device that controls the wafer processing unit and the scrubber. The scrubber has a function to operate to increase or decrease an amount to reduce the impact gas caused by the scrubbing process in response to a command signal received or a signal indicating a different amount of the impact gas. The control device transmits beforehand scrubbing operation information for the scrubber, the scrubbing operation information changing an operating state of the scrubber to enable the scrubbing process of the exhaust gas based on a processing condition of the wafer in the wafer processing unit obtained in advance.

### Advantageous Effects of Invention

According to the present invention, it is possible to provide a wafer processing apparatus that can more appropriately reduce the impact gases in the exhaust gas. Furthermore, it is possible to reduce the operating costs of the wafer processing apparatus.

### BRIEF DESCRIPTION OF DRAWINGS

FIG. 1 is a schematic diagram showing the overall configuration of a wafer processing apparatus according to an embodiment.

FIG. 2 is a cross-sectional view schematically showing an example of the configuration of a plasma etching device provided in a wafer treater according to an embodiment.

FIG. 3 is a block diagram showing the general configuration of a host computer, which is a control device according to an embodiment.

FIG. 4 is a graph showing changes in the amount of thermal energy necessary for the detoxification of impact gases in the exhaust gas.

FIG. 5 is a graph showing another example of changes in the amount of thermal energy necessary for the detoxification of impact gases in the exhaust gas.

FIG. 6 is a graph showing changes over time in the total amount of necessary thermal energy and the input energy amount.

### DESCRIPTION OF EMBODIMENTS

In the following, an embodiment of the present disclosure will be described in detail with reference to the drawings. In the drawings, the same parts are typically assigned with the same reference numerals, and repetitive descriptions are omitted. The representation of the components in the drawings is schematic to facilitate an understanding of the invention and may be exaggerated in width, thickness, shape, and the like, compared to actual forms. However, these representations are merely examples and do not limit the interpretation of the present disclosure.

### <Overall Configuration of Wafer Processing Apparatus>

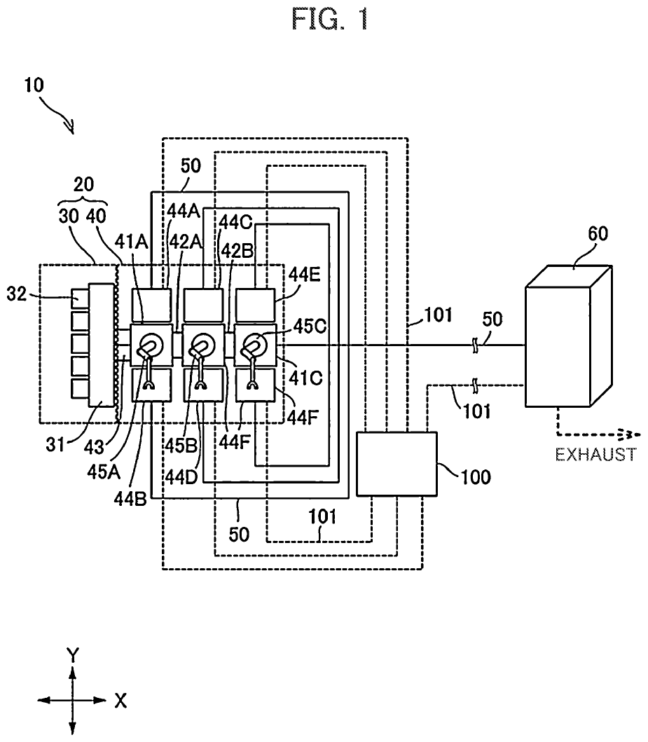

First, the overall configuration of a wafer processing apparatus will be described. FIG. 1 is a schematic diagram showing the overall configuration of a wafer processing apparatus according to an embodiment.

As shown in FIG. 1, a wafer processing apparatus 10 includes a wafer processing unit 20 that performs the processing of wafers, and a host computer 100 that controls the operation of the wafer processing unit 20. The wafer processing apparatus 10, as an example, includes one wafer processing unit 20, but may include a plurality of wafer processing units 20. In this case, the operation of the plurality of the wafer processing units 20 may be controlled by a single host computer 100.

The wafer processing unit 20 includes an atmospheric side block 30 and a vacuum side block 40. The atmospheric side block 30 is a component in which substrate-shaped samples such as semiconductor wafers as a processed target under atmospheric pressure are transported, and positioned for storing. The vacuum side block 40 is a block in which substrate-shaped samples such as wafers are transported under a pressure reduced from an atmospheric pressure and processed in a predetermined vacuum processing chamber.

### <Atmospheric Side Block>

The atmospheric side block 30 has an atmospheric transport vessel 31, which is a substantially rectangular box-shaped housing equipped with an atmospheric side transport robot (not shown) inside its waiting transport room. Additionally, the atmospheric side block 30 includes a plurality of FOUP stands 32 on the front side of the atmospheric transport vessel 31. FOUPs (Front Opening Unified Pods) in which substrate-shaped samples (hereinafter referred to as wafers) such as a semiconductor wafer as a processed target for processing or cleaning are stored, are placed on the FOUP stands 32.

### <Vacuum Side Block>

The vacuum side block 40 is a block joined to a vessel which is capable of maintaining a pressure having a high vacuum, and the entire inside thereof is a space which is maintained under reduced pressure. The vacuum side block 40 of the present disclosure is placed behind the atmospheric side block 30 and is connected to the atmospheric side block 30. The vacuum side block 40 includes a plurality of vacuum transport vessels 41A to 41C, which are vacuum vessels with vacuum transport rooms inside in which wafers are transported. In some cases, the plurality of vacuum transport vessels 41A to 41C is collectively referred to as the vacuum transport vessel 41.

Those vacuum transport vessels 41 are connected in the front-rear direction of the wafer processing unit 20 with such that insides of the vacuum transport vessels 41 are communicated with each other sandwiching a plurality (two in the present embodiment) of intermediate chambers 42A and 42B in which the wafer is housed. In some cases, the plurality of intermediate chambers 42A to 42B is collectively referred to as the intermediate chamber 42. The front-rear direction of the wafer processing unit 20 refers to the direction in which the plurality of vacuum transport vessels 41 is arranged side by side, indicated as the X direction in FIG. 1. The atmospheric side block 30 side is referred to as the front direction, and the vacuum side block 40 side is referred to as the rear direction. Furthermore, the direction orthogonal to the front-rear direction of the wafer processing unit 20 is referred to as the left-right direction, indicated as the Y direction in FIG. 1.

The vacuum transport vessel 41, which has an internal vacuum transport room, is a box-shaped vacuum vessel with a planar shape that is rectangular or regarded as approximately rectangular. To the surfaces of the side walls of the vacuum transport vessel 41 in the front-rear (X) and left-right (Y) directions of the wafer processing unit 20, in addition to the intermediate chamber 42, a lock chamber 43 or a plurality of water treaters 44 are connected, which are other vacuum vessels. In other words, each of the plurality of vacuum transport vessels 41 has a plurality (two in the present embodiment) of wafer treaters 44 connected to two sides in which neither the lock chamber 43 nor the intermediate chamber 42 are connected.

More specifically, two wafer treaters 44A and 44B are connected to the left-right directional side walls of the vacuum transport vessel 41A. Two wafer treaters 44C and 44D are connected to the left-right directional side walls of the vacuum transport vessel 41B. Wafer treaters 44E and 44F are connected to the left-right directional side walls of the vacuum transport vessel 41C. In some cases, the plurality of wafer treaters 44A to 44E is collectively referred to as the wafer treater 44. The pressure in the inside of each wafer treater 44 is reduced, and the processing of wafers loaded through the vacuum transport vessel 41 is performed in the pressure-reduced inside.

Each vacuum transport vessel 41 is a unit that includes a vacuum vessel with an approximately rectangular planar shape. On the inside of each vacuum transport vessel 41, a vacuum transport room is placed. In the inside of the vacuum transport rooms of the vacuum transport vessels 41A to 41C, vacuum transport robots 45A to 45C are respectively placed.

The vacuum transport robots 45A to 45C hold wafers in the vacuum transport rooms of the vacuum transport vessels 41A to 41C, and transport the held wafers to wafer treaters 44A to 44E and the like. In some cases, the plurality of vacuum transport robots 45A to 45C is collectively referred to as the vacuum transport robot 45.

More specifically, the vacuum transport robot 45 places wafers on the tip end of its arm and loads and unloads the wafers between the vacuum transport room and the wafer treater 44, or between any one of the lock chamber 43 or the intermediate chamber 42. Although not shown in the drawings, between the wafer treater 44, the lock chamber 43, the intermediate chamber 42, and the vacuum transport vessel 41, there is a gate, which is a passage through which the wafers held on the tip end of the arm of the vacuum transport robot 45 is transported, and gate valves that can hermetically seal and open each opening of the passages.

The intermediate chamber 42 is equipped with the function of a relay room in which wafers are temporarily stored when the wafers are transferred between the adjacent vacuum transport vessels 41. For example, it is assumed that a wafer placed in the lock chamber 43 is transported by the vacuum transport robot 45A placed in the vacuum transport vessel 41A and the wafer is stored in the intermediate chamber 42A. The wafer placed in the intermediate chamber 42A is then unloaded from the intermediate chamber 42B by the vacuum transport robot 45B placed in the vacuum transport vessel 41B and transported to the wafer treaters 44A and 44B joined to the vacuum transport vessel 41B, or to the intermediate chamber 42B.

The lock chamber 43 is placed at the position on the front-most side of the vacuum side block 40, i.e., closest to the atmospheric side block 30. More specifically, the lock chamber 43 is a sealed vacuum vessel placed between the vacuum transport vessel 41A and the atmospheric transport vessel 31 of the atmospheric side block 30.

The lock chamber 43 allows the exchange of wafers while varying the pressure between atmospheric pressure and vacuum within the chamber, with wafers placed inside, between the inside of the atmospheric transport vessel 31, which is at approximately atmospheric pressure, and the inside of the vacuum transport vessel 41A, the pressure of which is at a predetermined vacuum level. Although it is fine that at least one lock chamber 43 is provided, multiple lock chambers can be provided as necessary.

Each wafer treater 44, as will be described in detail later, includes, for example, is formed of a vacuum vessel, a mechanism that generates an electric field and a magnetic field surrounding the upper and peripheral parts of the vacuum vessel, and an exhaust mechanism including a vacuum pump that exhausts the inside of the processing chamber inside the vacuum vessel, the pressure inside the vessel to be reduced, and the like. In the processing chamber inside the vacuum vessel, etching, ashing, or other processes are performed on the wafers. Each wafer treater 44 is connected to the host computer 100 equipped in the wafer processing apparatus 10 through communication path 101 with communications permitted.

### <Example of Wafer Treater>

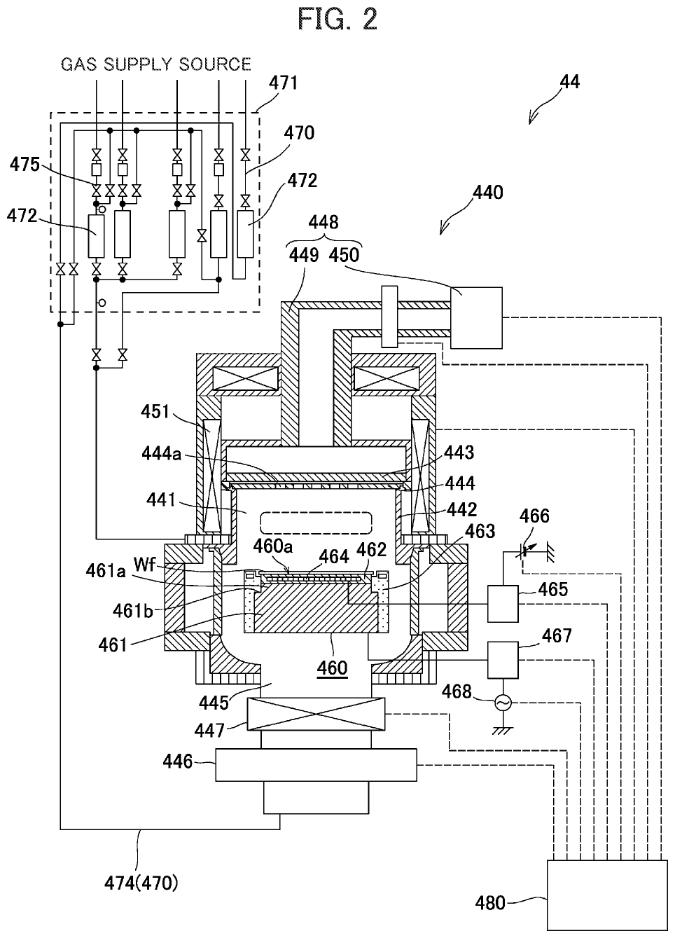

Next, an example of the structure of the wafer treater 44 will be described. FIG. 2 is a cross-sectional view schematically showing an example of the configuration of a plasma etching device provided in a wafer treater.

As shown in FIG. 2, the wafer treater 44 according to the present embodiment includes a plasma etching device 440. The plasma etching device 440 uses an electric field of microwaves to form plasma, generates Electron Cyclotron Resonance (ECR) with the microwave electric field and magnetic field to form plasma, and uses the plasma for etching substrate-shaped samples such as semiconductor wafers.

The plasma etching device 440 includes a vessel which includes therein a processing chamber 441 in which plasma is formed, for example, includes a vacuum vessel 442. The upper part of the processing chamber 441, which is in a cylindrical shape, is sealed by a disc-shaped dielectric window 443 made of quartz, for example. That is, the dielectric window 443 is provided as a lid member that seals the upper part of the processing chamber 441 and forms a part of the vacuum vessel 442. A sealing member is placed between the vacuum vessel 442 and the dielectric window 443 to ensure the airtightness of the inside of the vacuum vessel 442 or the processing chamber 441.

Below the dielectric window 443, a shower plate 444 that forms the circular ceiling surface of the processing chamber 441 is provided. The shower plate 444, which is disc-shaped with multiple gas introduction holes 444a centrally located and penetrating through the shower plate 444, introduces gases for etching into the processing chamber 441 through the gas introduction holes 444a. The shower plate 444 is made of a dielectric material such as quartz.

At the bottom of the vacuum vessel 442, an exhaust port 445 leading to the processing chamber 441 is provided. Below the processing chamber 441, there are provided a vacuum pump 446, such as a turbo molecular pump, which exhausts and depressurizes the gas inside the processing chamber 441, and an exhaust volume control valve 447 that increases or decreases the area of the passage to regulate the flow rate or speed of the exhaust. The exhaust port 445 of the vacuum vessel 442 is connected to the inlet of the vacuum pump 446 through the exhaust volume control valve 447. The outlet of the vacuum pump 446 is joined to the end of the exhaust pipe 50 shown in FIG. 1. The exhaust gas discharged from the outlet of the vacuum pump 446 is supplied to the scrubber 60, which will be described later, through the exhaust pipe 50.

Above the vacuum vessel 442, there is provided an electric and magnetic field forming unit 448 that forms an electric field and a magnetic field to generate plasma in the processing chamber 441. The electric and magnetic field forming unit 448 includes a waveguide 449 and an electric field generating power source 450. The high-frequency electric field oscillated by the electric field generating power source 450 is transmitted inside the waveguide 449 and introduced into the processing chamber 441. For example, the electric field generating power source 450 is a microwave power source, using microwaves with a frequency of 2.45 GHz, for example.

Around the lower end of waveguide 449 and around the periphery of the vacuum vessel 442, magnetic field generating coils 451 are placed. The magnetic field generating coils 451 are formed of electromagnets and yokes that form a magnetic field by supplying direct current.

Below the space in which plasma is formed inside the processing chamber 441, a wafer mounting electrode 460 is placed. The wafer mounting electrode 460 has a cylindrical protrusion in the central upper part, the surface of which is higher than the outer periphery, and the upper surface of this protrusion is provided with a mounting surface 460a on which a sample (processing object), i.e., a wafer Wf, is placed. The wafer mounting electrode 460 is placed such that its mounting surface 460a faces the shower plate 444 or the dielectric window 443.

For example, the wafer mounting electrode 460 includes an electrode base material 461, a dielectric film 462 provided on the electrode base material 461, and a susceptor ring 463. The electrode base material 461 has a protrusion 461a in the central upper part and a recessed part 461b surrounding the protrusion 461a. Although not shown in the drawing, the protrusion 461a of the electrode base material 461 has a circular shape in a plan view and is provided in the central part of the electrode base material 461. The recessed part 461b is provided in a ring shape around the protrusion 461a in a plan view. The upper surface of the protrusion 461a forms the mounting surface 460a of the wafer mounting electrode 460. The surface of the protrusion 461a is covered with the dielectric film 462.

Inside the dielectric film 462, there is provided a conductive film 464 made of a plurality of conductive materials. The conductive film 464 is connected to a direct current source 466 through a high-frequency filter 465. When a direct current is supplied to the conductive film 464, the wafer Wf is chucked to the mounting surface 460a through the dielectric film 462 on the conductive film 464. The conductive film 464 serves as an electrostatic chuck electrode.

The electrode base material 461 is connected to a high-frequency power source 468 through a matcher 467. The high-frequency power source 468 and the matcher 467 are placed at locations closer than the distance between the high-frequency filter 465 and the conductive film 464. Moreover, the high-frequency power source (RF power source) 468 is grounded.

During the processing of the wafer Wf, high-frequency power of a predetermined frequency from at least one high-frequency power source (RF power sources) 468 or a plurality of high-frequency power sources (RF power sources) 468, is supplied to the electrode substrate 461 (i.e., the sample stage). This forms a bias potential above the wafer Wf, which is held by suction on the mounting surface 460a through the dielectric film 462, the bias potential having a distribution corresponding to the difference between the plasma potential and the potential of the electrode substrate 461.

Although not shown in the drawing, inside the electrode substrate 461, there are provided coolant flow channels spirally or concentrically arranged multiple times around the central axis in the vertical direction of the electrode substrate 461. The coolant flow channels are provided to cool the wafer mounting electrode 460. The inlet and outlet of the coolant flow channels in the electrode substrate 461 are connected to a temperature regulator that adjust the temperature of the coolant with a piping. The coolant, which changes its temperature through heat exchange while flowing through the coolant flow channels in the electrode substrate 461, is then recirculated into the electrode substrate 461 after being brought to a specified temperature range within the temperature regulator.

On the recessed part 461b of the electrode substrate 461, the ring-shaped susceptor ring 463 surrounding the protrusion 461a is placed. The susceptor ring 463 is formed of at least one member made of a dielectric material such as quartz or alumina ceramics. Since the side surface of the protrusion 461a and the bottom surface of the recessed part 461b of the electrode substrate 461 are covered at least by the susceptor ring 463, this prevents damage to the electrode substrate 461 from plasma.

In the plasma etching device 440 thus configured, microwaves are oscillated from the electric field generation power source 450 in a state in which the treatment gas is introduced into the processing chamber 441 through the gas introduction holes 444a of the shower plate 444. The microwave electric field passes through the dielectric window 443 and the shower plate 444, and is supplied downward from above into the processing chamber 441. In addition, a magnetic field generated by the direct current supplied to the magnetic field generation coil 451 is also supplied to the inside of the processing chamber 441, causing an interaction with the microwave electric field and generating ECR (Electron Cyclotron Resonance). Through the ECR, atoms or molecules of the treatment gas are excited, dissociated, or ionized, producing a high-density plasma in the processing chamber 441.

The treatment gas is supplied to the plasma etching device 440 from a gas supply source placed below the floor of the building in which the plasma etching device 440 is installed, through a piping 470. The gas supply sources are provided for each type of gas. The piping 470 extends from each gas supply source for each type of gas. Along the way of the piping 470, an integrated gas box 471 is placed. Inside the integrated gas box 471, there are provided a plurality of pipings 470 and a plurality of mass flow controllers (MFC) 472, and the like, which adjust the flow rate or speed of various types of gas. The plurality of pipings 470 is bundled inside the integrated gas box 471 into a plurality of gas supply pipes 474, and the pipings 470 extend outside the box.

The treatment gas is introduced into the gap between the dielectric window 443 and the shower plate 444 through the gas supply pipe 474 (piping 470), and diffused inside the processing chamber 441. The flow of the treatment gas supplied into the processing chamber 441 through the gas introduction holes 444a is adjusted by an opening and closing valve 475 placed in the gas supply pipe 474.

As the treatment gas, for example, a reactive gas that reacts with the film as a processed target on the surface of the wafer, or a reactive gas generated inside the plasma, is used. Furthermore, as the treatment gas, a mixed gas including the reactive gas described above and an inert gas that dilutes the reactive gas are used. The wafer processing in each wafer treater 44, including the plasma etching device 440, has multiple steps using different treatment gases under different conditions. As described above, the treatment gases used in each step include impact gases.

Moreover, the wafer treater 44 includes a controller 480 that controls the plasma etching device 440, As shown in FIG. 2, a plurality of apparatus constituting the plasma etching device 440 such as the electric field generating power source 450, the magnetic field generating coil 451, the high-frequency power source 468, the high-frequency filter 465, the direct current source 466, the matcher 467, and the like is communicatively connected to the plasma etching device 440 by wired or wireless means. The operations of the components forming the plasma etching device 440 are appropriately controlled through the controller 480.

The controller 480 includes a processor such as a CPU, a memory device having an HDD, memory, and the like, and an interface with external communication devices, in wired or wireless manners, in a configuration in which these components are in connection that allows communication through wired or wireless communication manners. The controller 480 is connected to the host computer 100 of the wafer processing apparatus 10 through a communication path 101 in a manner that allows communications, and the controller 480 transmits operational state information, which indicates the operating states of each device forming the plasma etching device 440, to the host computer 100, In other words, the wafer treater 44 transmits operational state information, indicating the operation and the presence or absence of errors of each device of the wafer treater 44, to the host computer 100.

Moreover, as will be detailed later, the host computer 100 transmits processing information (processing recipes) that includes wafer processing conditions, as well as command signals, and the like, to the wafer treater 44 (controller 480). The controller 480 appropriately controls the operations of each device of the plasma etching device 440 based on the received processing information and command signals. In other words, each device of the wafer treater 44 is appropriately controlled based on processing information and command signals transmitted from the host computer 100.

### <Scrubber and Exhaust Pipe>

Each wafer treater 44 included in the wafer processing unit 20 is connected to the scrubber 60 through the exhaust pipe 50, as described above (see FIG. 1). For example, the wafer treater 44 includes the plasma etching device 440, and the exhaust pipe 50 is connected to the exhaust mechanism of the plasma etching device 440. More specifically, the exhaust pipe 50 is joined to the outlet of the vacuum pump 446 placed below the plasma etching device 440, forming the exhaust path of the wafer processing unit 20.

The exhaust gas exhausted from the plasma etching device 440 passes through the inside of the exhaust pipe 50 and is transferred outside the wafer processing unit 20. The exhaust gas includes treatment gases supplied to the processing chamber 441 of the vacuum vessel 442 of the plasma etching device 440 and used for wafer processing, as well as waste gases that are exhausted without being supplied to the processing chamber.

In the present embodiment, the downstream end of the exhaust pipe 50 in the flow direction of the exhaust gas is joined to the scrubber 60. The exhaust gas discharged from the wafer processing unit 20 is supplied to the scrubber 60 through the exhaust pipe 50. The scrubber 60 is equipped with a function to heat and decompose the impact gases contained in the exhaust gas by applying thermal energy to reduce or remove their environmental impact and harmfulness.

For example, the scrubber 60 includes an internal combustion chamber in which the exhaust gas containing impact gases is introduced into the combustion chamber to ignite, or a combustible gas is introduced into the combustion chamber along with the exhaust gas to ignite. The impact gases are, as described above, certain types of gases contained in the exhaust gas that are considered to have a high environmental impact or be harmful to humans and the environment.

Therefore, the heating and decomposition of the impact gases reduce the amounts of impact gases in the exhaust gas. In other words, the heating and decomposition of the impact gases reduce the impact or harmfulness of the original exhaust gas. The process of decomposing the impact gases in the exhaust gas to a degree in which the impact on the environment or the harmfulness to humans and the environment is sufficiently small is referred to as the scrubbing process. The operation of the scrubber 60 that performs this process is referred to as the scrubbing operation.

The exhaust pipe 50 is placed below the floor of the building in which the wafer processing unit 20 is installed, with one end joined to the exhaust mechanism of the plasma etching device 440 and the other end joined to the scrubber 60. The scrubber 60 is placed in another space below the floor of the building in which the wafer processing unit 20 is installed. The exhaust gas discharged from the wafer processing unit 20 is supplied to the scrubber 60 through the exhaust pipe 50, in which the impact gases are heated and decomposed in the combustion vessel, and then exhausted outside the building through an exhaust path not shown.

The scrubber 60 of the present embodiment is equipped with a function to increase or decrease the amount by which the scrubber 60 reduces impact gases in the exhaust gas through the scrubbing process, according to received command signals or signals indicating different amounts of impact gases. More specifically, the scrubber 60 has the following functions based on the received command signals or signals indicating different amounts of impact gases.

In the case in which the amount of impact gases in the exhaust gas increases with changes in the wafer processing conditions in each wafer treater 44, the scrubber 60 operates with an increase in the amount of the impact gases in the exhaust gas through the scrubbing process, making it possible to scrub the exhaust gas. Specifically, the scrubber 60 operates by increasing the amount of thermal energy (heating amount) applied to the impact gases below the current level. In other words, the scrubber 60 changes its operating state and operates in a state in which the heating or thermal energy amount applied to the impact gases is increased above the current level.

On the other hand, in the case in which the amount of impact gases in the exhaust gas decreases with changes in the wafer processing conditions in each wafer treater 44, the scrubber 60 decreases the amount by which impact gases in the exhaust gas are reduced through the scrubbing process as the scrubber 60 is capable of scrubbing the exhaust gas. For example, the scrubber 60 operates by decreasing the amount of thermal energy (heating amount) applied to the impact gases below the current level. In other words, the scrubber 60 changes its operating state and operates in a state in which the thermal energy amount applied to the impact gases within the range possible for the scrubbing process is decreased.

Thus, the scrubber 60 is equipped with a function to operate by increasing or decreasing the amount by which the scrubber 60 reduces impact gases in the exhaust gas through the scrubbing process. Consequently, the operating state of the scrubber 60 is appropriately changed according to the amount of impact gases. Therefore, it is possible to sufficiently reduce the impact gases in the exhaust gas through the scrubbing process, and it is possible to reduce the operating costs of the scrubber 60. As a result, it is possible to reduce the operating costs of the wafer processing apparatus 10. Note that as will be described in detail later, the adjustment of the operating state of the scrubber 60 is performed based on the scrubbing operation information (also referred to as a signal indicating scrubbing operation information) transmitted from the host computer 100, which is a control device.

### <Host Computer>

As described above, the wafer processing apparatus 10 includes the host computer 100, which is the control device that controls the operation of each device in the wafer processing unit 20. The host computer 100 is connected to each wafer treater 44, and other components of the wafer processing unit 20 including components forming each wafer treater 44 through the communication path 101, allowing transmission and reception of data and signals. The plasma etching device 440 included in each wafer treater 44 is controlled based on command signals and the like transmitted from the host computer 100.

The host computer 100 is also connected to the scrubber 60 through communication path 101. The host computer 100 is configured to allow the exchange of data and signals with the wafer processing unit 20 and the scrubber 60 through communication path 101. The operation of the scrubber 60 is also controlled based on command signals and the like transmitted from the host computer 100.

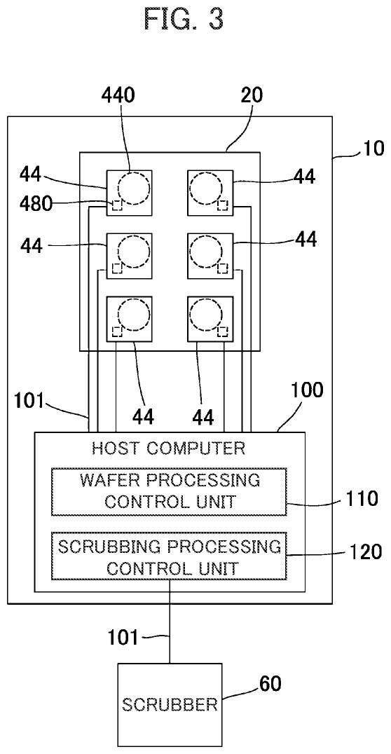

FIG. 3 is a block diagram showing the schematic configuration of a host computer, which is a control device according to an embodiment. As shown in FIG. 3, the host computer 100 includes a wafer processing control unit 110 and a scrubbing processing control unit 120.

The wafer processing control unit 110 controls the operation of each device in the wafer processing unit 20. More specifically, the wafer processing control unit 110 acquires processing information (processing recipes) including wafer processing conditions in the wafer processing unit 20 and the operating conditions of each device in the wafer processing unit 20, and transmits the processing information to the wafer processing unit 20. The wafer processing control unit 110 receives information indicating the operating state, such as operation and the presence or absence of errors, transmitted from each device in the wafer processing unit 20. Additionally, the wafer processing control unit 110 transmits command signals as necessary to adjust processing conditions and operating conditions.

The wafer processing control unit 110, for example, acquires the above processing information stored in the host computer 100 and transmits the acquired processing information and command signals to the controllers 480 of each plasma etching device 440 in the wafer treaters 44. The controller 480 appropriately controls the operation of the plasma etching device 440 based on the received processing information and command signals.

Here, the processing information may include information about the treatment gases supplied to the processing chamber 441 of the plasma etching device 440 and waste gases (referred to as gas information). Additionally, this gas information may include the information such as the flow rate per unit time of the treatment gases or waste gases supplied to the processing chamber 441 during the processing of wafers in the plasma etching device 440, and the total supply amount in the processing step of the wafer. Further, the gas information may include physical information of the impact gases, such as flow rate per unit time of impact gases in the exhaust gas, the composition of impact gases, the molecular weight and density of the components, and the activation energy or reaction heat for each component of the impact gases.

The processing information may also include condition information for the scrubbing operation based on the gas information and the like. For example, condition information for the scrubbing operation may include the amount of thermal energy necessary to be applied to the exhaust gas by the scrubber 60 to achieve the scrubbing process of impact gases and the like. Moreover, the condition information for the scrubbing operation may include time for the scrubbing operations and the ratio of values of the amount of thermal energy to be input by the scrubbing process to the maximum value of the amount of thermal energy that can be input by the scrubber 60, for example.

On the other hand, the scrubbing processing control unit 120 controls the operating state of the scrubber 60. For example, the scrubbing processing control unit 120 transmits scrubbing operation information, including the conditions for the scrubbing process to be performed during a predetermined period from a predetermined time, to the scrubber 60 at a predetermined timing.

More specifically, the scrubbing processing control unit 120 acquires the above processing information, including the wafer processing conditions in each wafer treater 44 and the like, before the start of the processing under those conditions. The scrubbing processing control unit 120 then calculates the scrubbing operation information, including the conditions for the scrubbing process, based on the processing information and the gas information related to the impact gases. The gas information may be acquired separately from the processing information or included in the processing information as described above.

Then, the scrubbing processing control unit 120 transmits the calculated scrubbing operation information to the scrubber 60 at a predetermined time or timing. The scrubbing operation information refers to information that achieves the scrubbing process for sufficiently scrubbing impact gases in the exhaust gas by the scrubber 60 or information that contributes to the execution of the scrubbing process.

When the scrubber 60 receives the scrubbing operation information transmitted from the scrubbing processing control unit 120, for example, the controller equipped in the scrubber 60 calculates operation commands (signals indicating operation commands) based on the scrubbing operation information and outputs these operation commands to each device in the scrubber 60. As a result, the operating state of the scrubbing operation of the scrubber 60 (i.e., the operating state) is appropriately adjusted such that the impact gases in the exhaust gas can be sufficiently reduced. In other words, the controller equipped in the scrubber 60 appropriately controls the operating state of the scrubber 60 based on the scrubbing operation information such that the impact gases in the exhaust gas can be sufficiently reduced.

In the present embodiment, the case is described in which the processing information is pre-stored in the host computer 100, but the processing information may also be pre-stored in the wafer processing unit 20.

In this case, the scrubbing processing control unit 120 receives the processing information transmitted from the wafer processing unit 20 and calculates the scrubbing operation information based on this processing information. After that, the scrubbing processing control unit 120 transmits the scrubbing operation information to the scrubber 60 at a predetermined time or timing. Alternatively, the scrubbing processing control unit 120 may transmit the scrubbing operation information to the scrubber 60 upon receiving a permission command (signal indicating a permission command) transmitted from the wafer processing unit 20 at a predetermined time or timing.

Furthermore, the wafer processing unit 20 may directly transmit the processing information to the scrubber 60, and the controller that includes a processor equipped in the scrubber 60 may calculate the scrubbing operation information based on this processing information and adjust the operating state of the scrubber 60.

Additionally, the wafer processing unit 20 may use its controller, including a processor, to calculate the scrubbing operation information based on the processing information and directly transmit the scrubbing operation information to the scrubber 60. In this case, although the controller 480 equipped in each wafer treater 44 may calculate the scrubbing operation information, for example, the wafer processing unit 20 may be equipped with an overall controller that is connected to multiple wafer treaters 44 (controllers 480) in a manner that allows communications. The overall control unit may calculate the scrubbing operation information based on the processing information as described above and transmit the scrubbing information to the scrubber 60.

Moreover, in the case in which the controller of the wafer processing unit 20 calculates the scrubbing operation information, this information may be transmitted to the scrubber 60 through the host computer 100. In this case, the host computer 100 may transmit the scrubbing operation information to the scrubber 60 at a predetermined time or timing or upon receiving a permission signal and the like from the wafer processing unit 20.

Furthermore, in the case in which the wafer processing unit 20 transmits the scrubbing operation information to the host computer 100, the scrubbing processing control unit 120 of the host computer 100 may calculate operation commands (instruction signals) indicating the conditions of the scrubbing operation of the scrubber 60 based on the scrubbing operation information and transmit these operation commands to the scrubber 60. The operation commands are calculated according to a predetermined algorithm based on the scrubbing operation information. In this case, the operation commands calculated by the scrubbing processing control unit 120 are included in a piece of the scrubbing operation information. Additionally, the processing information used to calculate the operation commands is also considered to be included in a piece of the scrubbing operation information.

For example, the scrubbing operation information may include information about the increase or decrease in the amount of the impact gas and operation commands for changing the operating state of the scrubber 60 to enable the scrubbing process of the increased or decreased amount of impact gas. In this case, the scrubbing processing control unit 120 transmits the scrubbing operation information to the scrubber 60 such that the operating state of the scrubber 60 is changed before processing wafers under the processing conditions acquired beforehand in the wafer processing unit 20.

### <Operation During Wafer Processing in Wafer Processing Unit>

Here, the operation during wafer processing in the wafer processing unit 20 will be described. When the wafer processing control unit 110 of the host computer 100 transmits the aforementioned processing information, and upon receiving this information, the wafer processing unit 20 starts processing wafers.

When the wafer processing starts, first, wafers stored in the FOUP placed on the FOUP stand 32 are taken out by an atmospheric side transport robot, not shown, and transported to the lock chamber 43.

In the lock chamber 43, in which wafers are stored and transported, valves are closed and sealed with the transported wafers stored, and the pressure is reduced to a predetermined level. After that, the valve on the side of the lock chamber 43 facing the vacuum transport vessel 41A is opened, communicating the lock chamber 43 with the vacuum transport vessel 41A.

The vacuum transport robot 45A extends its arm into the lock chamber 43, receives the wafer on the wafer support at the end of its arm, and unloads the wafer into the vacuum transport vessel 41A, Furthermore, the vacuum transport robot 45A loads the wafer on its arm along a predetermined transport path into any one of the wafer treaters 44A and 44B, or the intermediate chamber 42A connected to the vacuum transport vessel 41A.

For example, wafers loaded into the intermediate chamber 42A are then unloaded from the intermediate chamber 42A to the vacuum transport vessel 418 by the vacuum transport robot 45B, and loaded along a predetermined transport path into one of the wafer treaters 44C, 44D, or the intermediate chamber 42B.

Furthermore, for example, wafers loaded into the intermediate chamber 42B are then unloaded from the intermediate chamber 42B into the vacuum transport vessel 41C by the vacuum transport robot 45C and loaded along a predetermined transport path into any one of the wafer treater 44E or the wafer treater 44E. For example, the wafers transported to each wafer treater 44 are loaded into the processing chamber 441 of the vacuum vessel 442 (processing chamber 441) of the plasma etching device 440.

In the present embodiment, the aforementioned valves are operated exclusively. For example, the wafers are loaded into the intermediate chamber 42B, the valve between the vacuum transport vessel 41B and the intermediate chamber 42B is closed, sealing the intermediate chamber 42B. After that, the valve between the intermediate chamber 42B and the vacuum transport vessel 41C is opened, and the vacuum transport robot 45C equipped on the vacuum transport vessel 41C is extended to transport the wafer into the vacuum transport vessel 41C. The vacuum transport robot 45C then transports the wafer on its arm into any one of the preset wafer treater 44E or the wafer treater 44F.

Furthermore, for example, in the case in which a wafer is transported to the wafer treater 44E, the valve opening and closing between the wafer treater 44E and the vacuum transport vessel 41C is closed, sealing the wafer treater 44E. After that, a treatment gas is introduced into the wafer treater 44E, into the processing chamber 441 of the plasma etching device 440, in the present embodiment, and the pressure inside this processing chamber 441 is adjusted to be suitable for processing. Then, an electric field or magnetic field is supplied to the processing chamber 441, this excites the treatment gas and forms plasma in the processing chamber 441, thus processing the wafer under specified conditions.

When wafers are processed by the plasma etching device 440, which forms a part of wafer treater 44, the exhaust gas is supplied from the processing chamber 441 to the scrubber 60 through the exhaust pipe 50. As will be described in detail later, the scrubber 60 performs the scrubbing processing of the exhaust gas. In other words, when the exhaust gas is supplied through the exhaust pipe 50, the scrubber 60 executes a scrubbing operation to scrub the exhaust gas.

When the processing of the wafer is completed, the vacuum transport robot 45C unloads the processed wafer into the vacuum transport vessel 41C and carries the wafer back to the lock chamber 43 through the reverse transport route used to load the wafer into the wafer treater 44E. After that, the wafer is transported from the lock chamber 43 back into the original FOUP by an atmospheric transport robot, not shown.

### <Scrubbing Process>

Next, a specific example of the exhaust gas scrubbing process carried out by the scrubber 60 connected to the wafer processing apparatus, especially about the setting changes in the amount of thermal energy, will be described.

As described above, the scrubber 60 performs the scrubbing process of the exhaust gas supplied through the exhaust pipe 50 when wafers are processed by the plasma etching device 440. The scrubber 60 is equipped with the function to increase or decrease the amount of the impact gas reduced by the scrubbing process based on the scrubbing operation information. In other words, the scrubber 60 has the function to change its operating state according to the changes in the amount of the impact gas in the exhaust gas, based on the scrubbing operation information, such as changing the conditions of the scrubbing process. The amount of the impact gas in the exhaust gas is calculated based on the aforementioned processing information.

In the present embodiment, changes in the operating state of the scrubber 60 are controlled based on the scrubbing operation information transmitted from the scrubbing processing control unit 120 of the host computer 100.

More specifically, the scrubbing processing control unit 120 transmits the scrubbing operation information to the scrubber 60 in advance, based on the aforementioned processing information obtained in advance, to change the operating state of the scrubber 60 to enable the scrubbing process of the exhaust gas. Transmitting the scrubbing operation information to the scrubber 60 in advance means, for example, transmitting the scrubbing operation information to the scrubber 60 before the start of wafer processing under the processing conditions in the wafer processing unit 20.

When the scrubber 60 receives the scrubbing operation information transmitted by the scrubbing processing control unit 120, the scrubber 60 changes its operating state to a scrubbing operation appropriate for changes (increase or decrease) in the amount of the impact gas in the exhaust gas, based on the received scrubbing operation information. In other words, upon receiving the scrubbing operation information, the scrubber 60 performs setting changes to increase or decrease the amount of thermal energy applied to the impact gas in the exhaust gas according to changes in the amount of the impact gas over time.

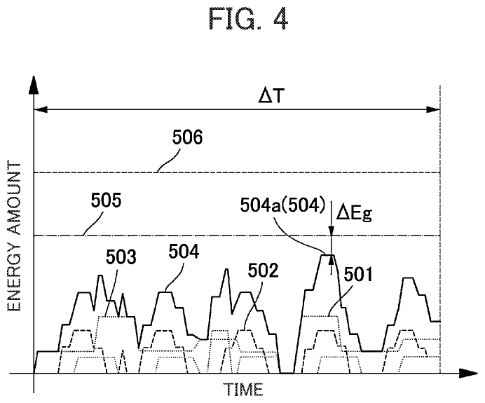

Here, the change in the amount of thermal energy necessary for the scrubbing process of the impact gas in the exhaust gas will be described with reference to FIG. 4. FIG. 4 is a graph showing the changes in the amount of thermal energy necessary for the scrubbing process of the impact gas in the exhaust gas, with the vertical axis representing the amount of thermal energy and the horizontal axis representing time.

The amount of thermal energy necessary to be applied to the impact gas in the exhaust gas in the scrubbing process shows similar changes as the flow rate of the impact gas changes. In other words, the graph in FIG. 4 can also be said to show the trend of changes in the flow rate of the impact gas.

FIG. 4 shows the thermal energy necessary for scrubbing when exhaust gas is supplied from the three plasma etching devices 440 forming the wafer treaters 44, to the scrubber 60. More specifically, FIG. 4 shows the amount of thermal energy (heating value) needed to scrub the impact gas contained in the exhaust gas of each of the three plasma etching devices 440, represented as three different dashed lines for a first value 501, a second value 502, and a third value 503, The value corresponding to the sum of the first value 501, the second value 502, and the third value 503 is represented as a fourth value 504, shown as a solid line in the figure.

The processing conditions, such as the type of treatment gas used, flow rate, and duration of use, change depending on the wafer processing performed in each wafer treater 44 (plasma etching device 440). In the present example, the amount of the impact gas in the exhaust gas of each wafer treater 44 changes in a step-like manner. In other words, the amount of the impact gas in the exhaust gas repeats variations such that the amount is set to a certain value from value zero for a certain period, then changing to a different fixed value for another period, or reverting back to zero value.

Therefore, the trajectory of the thermal energy amount necessary to scrub the impact gas in the exhaust gas discharged from each plasma etching device 440 (in the following, also referred to as the necessary thermal energy amount value), i.e., the trajectories of the first value 501, the second value 502, and the third value 503 also change over time in a similar step-like manner. Naturally, the fourth value 504, which is the value of the total necessary thermal energy amount for scrubbing the sum (total) of the impact gas amounts in the exhaust gases from the plasma etching devices 440 (in the following, referred to as a total necessary thermal energy amount value), shows similar fluctuations as the sum (total) of the impact gas amounts in the exhaust gases from the plasma etching devices 440.

More specifically, the fourth value 504 depicted by a solid line in FIG. 4, the total thermal energy amount value, is the trajectory of the total thermal energy amount value during any processing period and fluctuates in a step-like manner over time (horizontal axis), similar to the first value 501, the second value 502, and the third value 503, which are the necessary thermal energy amount values. The fourth value 504 at each time point nearly coincides with the sum of the first value 501, the second value 502, and the third value 503 at respective times.

Upon receiving the scrubbing operation information, the scrubber 60 appropriately sets the thermal energy amount value to be applied and imparted to the impact gas in the exhaust gas during the scrubbing process (in the following, referred to as the input energy amount value) based on the received information. In FIG. 4, the input energy amount value is represented as a fifth value 505 with an alternate long and short dash line. The scrubber 60 sets the fifth value 505, which is the input energy amount value, to a value that can scrub the impact gas in the exhaust gas within a range from zero to its maximum possible thermal energy amount, represented as a sixth value 506 in FIG. 4 (shown with a dash-dot line). In other words, the scrubber 60 sets the fifth value 505, which is the input energy amount value, to a value ranging from the fourth value 504 during a predetermined period ΔT to the same or smaller than the sixth value 506 based on the scrubbing operation information.

In the present embodiment, during the predetermined period ΔT in the wafer processing implementation period in the wafer processing unit 20, the input energy amount value of the scrubber 60 is set to be less than 100% of the operating impact rate. The operating impact rate here refers to the ratio of the set input energy amount value (the fifth value 505) to the maximum thermal energy amount that the scrubber 60 can input (the sixth value 506).

Furthermore, in the present embodiment, the scrubber 60 sets a value, as the input energy amount value (the fifth value 505) during the predetermined period ΔT, in which an energy amount ΔEg as a safety margin is added to the total necessary thermal energy amount value (the fourth value 504) during the same period, based on the scrubbing operation information.

More specifically, as shown in FIG. 4, the fourth value 504, which is the total thermal energy amount value during the scrubbing period ΔT, increases and decreases in a step manner including multiple steps. The scrubber 60 sets, as the fifth value 505, which is the input energy amount value during the predetermined period ΔT, a value in which the energy amount ΔEg as a safety margin is added to a maximum value 504a of the fourth value 504, which is the total necessary thermal energy amount value during the predetermined period ΔT.

In other words, the scrubber 60 maintains the input energy amount value during the predetermined period ΔT at a constant level of the maximum value of the total thermal energy amount value+α. The “+α” corresponds to the energy amount ΔEg as a safety margin. This energy amount ΔEg only has to be set appropriately, depending on the estimated necessary sufficient margin.

As described above, in the present embodiment of the wafer processing apparatus 10, the scrubbing processing control unit 120 transmits the scrubbing operation information in advance to the scrubber 60, which then sets the thermal energy amount to be applied to the impact gas in the exhaust gas (input energy amount) appropriately based on the received information. This ensures that the scrubber 60 can properly carry out the scrubbing operation to suppress or reduce the harmfulness and environmental impact of the impact gas, even though there are unintended fluctuations in the operation of the scrubber 60 or the wafer processing unit 20.

Moreover, the scrubber 60 is set not only to switch on and off the operation state, which is either at its maximum or zero operating impact rate, during wafer processing in the wafer processing unit 20, but also to set the input energy amount needed for scrubbing the impact gas in the exhaust gas considering a safety margin. This reduces the likelihood of the scrubber 60 operating at an excessively high impact rate, thus reducing the operating costs of the scrubber 60.

### <Another Example of Scrubbing Process>

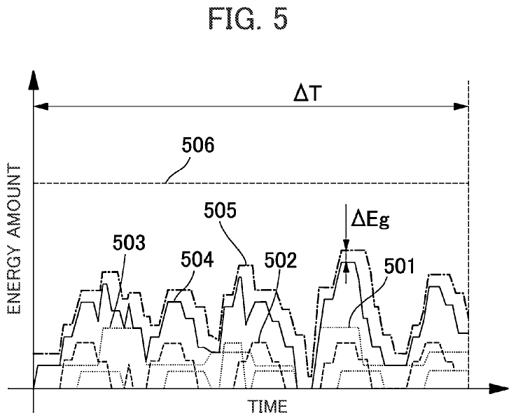

FIG. 5 is a graph showing another example of the changes in the necessary thermal energy amount values, similar to FIG. 4, with the vertical axis representing the thermal energy amount and the horizontal axis representing time. In the example shown in FIG. 4, the fifth value 505, which is the input energy amount value, is kept constant during a predetermined period ΔT. In contrast, the example in FIG. 5 shows that the input energy amount value changes following the fluctuations in the necessary thermal energy amount values during the predetermined period ΔT. In other words, in the example shown in FIG. 5, the period during which the fifth value 505, which is the input energy amount value, remains constant is shorter than the predetermined period ΔT. That is, during the predetermined period ΔT, the value in which the energy amount ΔEg is added to the fourth value 504, which is the total necessary thermal energy amount value fluctuating over time, is set as the fifth value 505, which is the input energy amount value.

Further elaborating, in the present example, the fifth value 505, which is the input energy amount value, increases or decreases more finely in accordance with the changes over time in the fourth value 504, which is the total necessary thermal energy amount value, compared to the example in FIG. 4.

This suppresses excessive thermal energy from being applied to the exhaust gas and further reduces the operating costs of the scrubber 60. As a result, the operating costs of the wafer processing apparatus 10 are reduced. Preferably, the interval for changing the input energy amount value is as short as possible. In other words, the interval at which the scrubber 60 obtains scrubbing operation information is preferably as short as possible. Particularly, the interval for changing the input energy amount value is preferably set to the smallest possible value that can be set in the wafer processing unit 20 or the scrubber 60.

### (Scrubbing Operation Flow in Pollution Control Device)

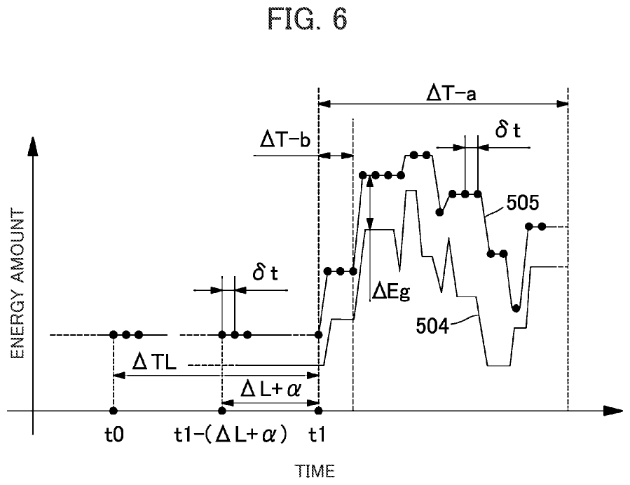

Next, using FIG. 6, the flow of the scrubbing operation in the scrubber 60 will be described. FIG. 6 is a graph showing changes over time in the total amount of necessary thermal energy value and the input energy amount value.

When the scrubbing operation is carried out in the scrubber 60, first, during the operating period of the wafer processing unit 20, the scrubbing processing control unit 120 obtains processing information (so-called processing recipe). More specifically, the scrubbing processing control unit 120 obtains the processing information for a predetermined period ΔT (the so-called processing recipe) at time (in the following, referred to as target time) from each sampling time, set at a predetermined sampling cycle δt, within the operating period after a specific time from each sampling time. For example, as shown in FIG. 6, at any given time to set at the sampling cycle δt, the scrubbing processing control unit 120 obtains processing information for the predetermined period ΔT from the target time t1 after a specific time ΔTL from time to.

The specific time ΔTL and the predetermined period ΔT are given periods set in advance and set to a preferred period, for example, based on the process steps and the number of wafers processed in the wafer treater 44.

FIG. 6 shows, as examples of the predetermined period ΔT, a first predetermined period ΔT-a and a second predetermined period ΔT-b. The first predetermined period ΔT-a is an example of a predetermined period ΔT that includes multiple steps (two or more) of the total necessary thermal energy amount value (the fourth value 504) fluctuating in a step manner, corresponding to the predetermined period ΔT shown in FIG. 5. On the other hand, the second predetermined period ΔT-b is an example of a predetermined period ΔT that is equal to or shorter than one step of the total necessary thermal energy amount value (the fourth value 504). Note that in other words, the second predetermined period ΔT-b is an example of a predetermined period ΔT that is equal to or shorter than the length of one processing step among several wafer processing steps.

Furthermore, the scrubbing processing control unit 120 uses the aforementioned processing information to calculate the maximum value of the total necessary thermal energy amount value during the predetermined period ΔT from the target time t1. That is, the scrubbing processing control unit 120 calculates the maximum value of the fourth value 504 shown in FIG. 6. Next, the scrubbing processing control unit 120 calculates the input energy amount value by adding a margin value ΔEg for safety to the maximum value of the total necessary thermal energy amount value, and stores this input energy amount value in the memory device of the host computer 100, setting the input energy amount value as the input energy amount value to be set to the scrubber 60 at the target time t1.

The scrubbing processing control unit 120 stores the processing information (recipe information) obtained during the predetermined period ΔT from the target time t1 at predetermined intervals as time-series data in a storage device. This processing information includes information such as the start and end times of wafer processing in each wafer treater 44 and the like. Additionally, the maximum value of the total necessary thermal energy amount calculated at each predetermined interval during the predetermined period ΔT from the target time t1 is also stored as time-series data.

In the present embodiment, the predetermined intervals at which each piece of time-series data is associated and stored for the predetermined period ΔT from the target time t1 are set as necessary. These predetermined intervals are set to a value, for example, equal to the predetermined sampling period δt. That is, the necessary thermal energy amount values are stored as time-series data at multiple times during the predetermined period ΔT from the target time t1, at each sampling interval δt. In the present example, the total necessary thermal energy amount value at the target time t1 after a specific time ΔTL from each sampling interval δt during the scrubbing operation is calculated and stored.

Furthermore, the maximum value of the total necessary thermal energy amount for the predetermined period ΔT from the target time t1 and the input energy amount value calculated based on this maximum value are stored as time-series data associated with the target time t1.

Thus, in the present example, as shown in FIG. 6, the input energy amount value for the target time t1 is calculated using processing information, which includes the processing recipe, physical information about the impact gas, and the like, obtained at time t0, which is a specific time ΔTL before the target time t1. This input energy amount value is then stored in the host computer 100.

Although the total necessary thermal energy amount value can be calculated at each sampling interval δt from any target time during the predetermined period ΔT, it is unnecessary at every sampling interval δt. This is because, for example, the total necessary thermal energy amount value for the target time t1 is sometimes stored as time-series data at a target time prior to the target time t1.

However, for example, at any given time t0, processing information, including the processing information for the predetermined period ΔT from the target time t1, is obtained, and a new total necessary thermal energy amount value is calculated and stored as time-series data associated with the predetermined period ΔT from the target time t1. Therefore, consequently, the maximum value of the newly calculated total necessary thermal energy amount value at the target time t1 and the setting value for the input energy amount of the scrubber 60 are calculated and stored, associated with the target time t1.

In this manner, the input energy amount values to be set in the scrubber 60 are calculated for each of multiple target times changing at each sampling interval δt over time. The calculated input energy amount values are transmitted to the scrubber 60 before the time during the scrubbing operation reaches the target time, as the calculated input energy amount values are to be set and realized at the respective target times.

In the present example, the input energy amount values (setting values) are transmitted from the host computer 100 to the scrubber 60 as scrubbing operation information before the actual target time. That is, the scrubbing operation information, including the input energy amount values, is transmitted in advance from the host computer 100 to the scrubber 60. Consequently, the scrubbing processing control unit 120 calculates and stores the time-series data of the input energy amount values during the scrubbing operation by the scrubber 60, before the actual time reaches the target time.

The signal indicating the input energy amount value to be set in the scrubber 60 at any target time, that is, the signal indicating the scrubbing operation information, has to be received by the scrubber 60 before reaching the respective target time. After receiving the signal indicating the scrubbing operation information, it takes a certain amount of time for the scrubber 60 to start and complete the setting change of the input energy amount value. Additionally, there is a time difference (lag) between the transmission of the signal indicating the scrubbing operation information by the scrubbing processing control unit 120 and the completion of the setting change by the scrubber 60, including the time it takes for the signal to be actually received by the scrubber 60. In other words, the scrubber 60 needs a predetermined transition time from the start of changing the operation state to the completion of the change in the operation state.

Considering the transition time (time difference), it is preferable to transmit the scrubbing operation information from the scrubbing processing control unit 120 to the scrubber 60 in advance, before the target time. For example, the scrubbing processing control unit 120 preferably transmits the scrubbing operation information to the scrubber 60 before the processing of wafers under previously obtained processing conditions begins, ensuring that the operating state of the scrubber 60 is changed accordingly.

For example, consider the time taken by the scrubber 60 to complete the setting change of the input energy amount value after receiving the signal indicating the scrubbing operation information, referred to as period ΔL. In the case in which this transition time ΔL occurs, the scrubbing processing control unit 120 preferably transmits the scrubbing operation information to the scrubber 60 at the following timing.

As shown in FIG. 6, the scrubbing operation information, including the input energy amount value to be set in the scrubber 60 at the target time t1, is transmitted by the scrubbing processing control unit 120 to the scrubber 60 at a time earlier than at least a first period ΔL before the target time t1, preferably earlier than the first period ΔL by an additional second period ΔL+α. In other words, the scrubbing processing control unit 120 transmits the scrubbing operation information to the scrubber 60 by time (t1−(ΔL+α)) earlier in the first period ΔL before the target time t1.

The length of the second period ΔL+α is preferably a value greater than the maximum value of the arrival time of the exhaust gas. It takes a certain time for the exhaust gas to travel from each wafer treater 44 to the scrubber 60. The arrival time of the exhaust gas varies depending on the flow speed of the exhaust gas and the length of the exhaust pipe 50, That is, the arrival time of the exhaust gas may vary between the wafer treaters 44. In such cases, the arrival time of the exhaust gas is represented by the longest time (maximum value) among the multiple wafer treaters 44.

During the period of scrubbing operation, the input energy amount value in the scrubber 60 is adjusted at any given timing. The input energy amount value changes following the increase or decrease in the necessary thermal energy amount value over time. It is necessary to suppress any shortfall in the input energy amount value. That is, it is necessary to suppress the occurrence that the exhaust gas is insufficiently treated and that impact gases remain due to inadequate settings in the input energy amount value. In other words, the operating state of the scrubber 60 has to be changed to enable the scrubbing process of the exhaust gas based on the scrubbing operation information.

Therefore, during the scrubbing operation, the total necessary thermal energy amount value or the input energy amount value set to be changed in the scrubber 60 is determined at multiple predetermined intervals. For example, in the case in which the input energy amount value determined at a first timing increases compared to the determination made at a second timing earlier than the first timing, the increase in the input energy amount value, caused by an increase in the impact gas in the exhaust gas reaching the scrubber 60, is completed before the exhaust gas arrives. Specifically, it is preferable to finish increasing the actual input thermal energy amount just before the exhaust gas reaches the scrubber 60.

On the other hand, in the case in which the input energy amount value and the like determined at a first timing decreases compared to the determination made at a second timing earlier than the first timing, the change in the input energy amount value, caused by a decrease in the impact gas in the exhaust gas, is to start after the exhaust gas has reached the scrubber 60. Specifically, it is preferable to finish reducing the input thermal energy amount just after the exhaust gas arrives at the scrubber 60.

Based on the aforementioned time-series data, in the case in which the input energy amount value to be set in the scrubber 60 at the target time t1 increases compared to the value at the sampling time just before the target time t1, then the scrubbing processing control unit 120 preferably transmits the scrubbing operation information, including the input energy amount value for the target time t1, just before or earlier than the time (t1−(ΔL+α)).

In other words, in the case in which the scrubbing processing control unit 120 determines, based on the processing information including the wafer processing conditions, that the amount of the impact gas at the target time t1 increases, the scrubbing processing control unit 120 preferably transmits the scrubbing operation information to the scrubber 60 such that the change in the operating state of the scrubber 60 is completed before the actual increase in the impact gas begins. For example, in the case in which the scrubbing processing control unit 120 determines an increase in the amount of the impact gas at the target time t1 based on the processing information, the scrubbing processing control unit 120 transmits the scrubbing operation information to the scrubber 60 to ensure that the operating state change is completed by the target time t1.

Specifically, in the case in which the scrubbing processing control unit 120 determines, based on the processing information, that the amount of the impact gas increases, the scrubbing processing control unit 120 preferably transmits the scrubbing operation information to the scrubber 60 immediately after obtaining the processing information.

On the other hand, in the case in which the input energy amount value to be set in the scrubber 60 at the target time t1 decreases compared to the value at the sampling time just before t1, the scrubbing processing control unit 120 preferably transmits the scrubbing operation information to the scrubber 60 after the second time, which is earlier by the transition time ΔT from the first time when the impact gas in the exhaust gas begins to decrease. For example, in the case in which the scrubbing processing control unit 120 determines, based on the processing information, that the amount of the impact gas decreases, the scrubbing processing control unit 120 preferably transmits the scrubbing operation information to the scrubber 60 after the second time, which is earlier by the period ΔL corresponding to the transition time from the target time t1 corresponding to the first time.

In other words, in the case in which the scrubbing processing control unit 120 determines, based on the processing information including the wafer processing conditions, that the amount of the impact gas at the target time t1 decreases, the scrubbing processing control unit 120 preferably transmits the scrubbing operation information to the scrubber 60 such that the change in the operating state of the scrubber 60 starts after the actual decrease in the impact gas begins. For example, in the case in which the scrubbing processing control unit 120 determines a decrease in the amount of the impact gas at the target time t1 based on the processing information, the scrubbing processing control unit 120 preferably transmits the scrubbing operation information to the scrubber 60 to ensure that the operating state change starts after the target time t1.

The scrubbing processing control unit 120 periodically obtains processing information, as described above. The scrubbing processing control unit 120 then compares the processing information obtained at any given timing with the information obtained at a time before that to determine whether the amount of the impact gas at the target time increases or decreases. Of course, the method used by the scrubbing processing control unit 120 to determine whether the amount of the impact gas increases or decreases is not specifically limited.

As described above, in the present example, in the case in which the input energy amount value in the scrubber 60 increases at any given target time, the operation to increase the input energy amount value in the scrubber 60 starts before the exhaust gas with increased impact gas reaches the device. On the other hand, in the case in which the input energy amount value decreases at any target time, the operation to reduce the input energy amount value in the scrubber 60 starts after the exhaust gas with reduced impact gas reaches the device.

As a result, it is possible to reduce the likelihood of the thermal energy (input energy amount) applied by the scrubber 60 to the impact gas in the exhaust gas falling below the necessary amount for adequate scrubbing. It is possible to suppress a situation in which the exhaust gas is insufficiently scrubbed, leaving residual impact gases. Consequently, it is possible to suppress the degradation of the safety of the operations of both the scrubber 60 and the wafer processing apparatus 10.

Moreover, according to the wafer processing apparatus 10 of the present disclosure, when the amount of the impact gas in the exhaust gas increases or decreases over time, it is possible to cause the scrubber 60 to perform the scrubbing processing of the impact gas while ensuring a safety margin, following the increase or decrease in the impact gas. Therefore, the environmental impact and harmfulness during the operation of the wafer processing apparatus 10 are reduced. The operating costs of the wafer processing apparatus 10 are also reduced.

As described above, the embodiment and representative modifications are described, and the technology described above is applicable to various other modifications other than the examples given. For example, the above-described modifications may be combined.

### LIST OF REFERENCE SIGNS

10: wafer processing apparatus, 20: wafer processing unit, 30: atmospheric side block, 31: atmospheric transport vessel, 32: FOUP stand, 40: vacuum side block, 41 (41A to 41C): vacuum transport vessel, 42 (42A, 42B): intermediate chamber, 43: lock chamber, 44 (44A to 44F): wafer treater, 45 (45A to 45C): vacuum transport robot, 50: exhaust pipe, 60: scrubber, 100: host computer (control device), 101: communication path, 110: wafer processing control unit, 120: scrubbing processing control unit, 440: plasma etching device, 441: processing chamber, 442: vacuum vessel, 443: dielectric window, 444: shower plate, 444a: gas introduction hole, 445: exhaust port, 446: vacuum pump, 447: exhaust volume control valve, 448: electric and magnetic field forming unit, 449: waveguide, 450: electric field generating power source, 451: magnetic field generating coil, 460: wafer mounting electrode, 461a: protrusion, 461b: recessed part, 462: dielectric film, 463: susceptor ring, 464: conductive film, 465: high-frequency filter, 466: direct current source, 467: matcher, 468: high-frequency power source (RF power source), 470: piping, 471: integrated gas box, 472: mass flow controllers (MFC), 474: gas supply pipe, 475: opening and closing valve, 480: controller

1. A wafer processing apparatus comprising:
a wafer processing unit that supplies a treatment gas to a vessel and processes a wafer that is placed in the vessel as a processed target, the wafer processing unit being joined to a scrubber that performs a scrubbing process to reduce an impact gas in an exhaust gas discharged from the vessel; and
a control device that controls the wafer processing unit and the scrubber, wherein
the scrubber has a function to operate to increase or decrease an amount to reduce the impact gas caused by the scrubbing process in response to a command signal received or a signal indicating a different amount of the impact gas, and
the control device transmits beforehand scrubbing operation information for the scrubber, the scrubbing operation information changing an operating state of the scrubber to enable the scrubbing process of the exhaust gas based on a processing condition of the wafer in the wafer processing unit obtained in advance.

2. The wafer processing apparatus according to claim 1,
wherein the scrubbing operation information includes information on an amount of the impact gas to increase or decrease, or an operation command that changes the operating state of the scrubber to enable the scrubbing process of the impact gas in the increased amount or the decreased amount, and
the control device transmits the scrubbing operation information for the scrubber such that the operating state of the scrubber is changed prior to processing the wafer under the processing condition obtained in advance.

3. The wafer processing apparatus according to claim 1,
wherein the control device obtains the processing condition for the wafer processing unit from target time set arbitrarily in a predetermined period before the target time, and
the control device transmits the scrubbing operation information for the scrubber to change the operating state of the scrubber at the target time to enable the scrubbing process of the exhaust gas based on the processing condition obtained.

4. The wafer processing apparatus according to claim 1,
wherein the control device transmits the scrubbing operation information for the scrubber including an energy amount necessary for the scrubbing process based on the processing condition for the wafer processing unit.

5. The wafer processing apparatus according to claim 1,
wherein the scrubber needs a predetermined transition time from start of changing the operating state to completion of the change in the operating state.

6. The wafer processing apparatus according to claim 1,
wherein the control device obtains the processing condition for the wafer processing unit from target time arbitrarily set in a predetermined period before the target time,
when the control device determines that an amount of the impact gas at the target time increases based on based on the processing condition, the control device transmits the scrubbing operation information for the scrubber such that changing the operating state of the scrubber is completed before the amount of the impact gas is started to increases, and
when the control device determines that an amount of the impact gas at the target time decreases based on the processing condition, the control device transmits the scrubbing operation information for the scrubber such that changing the operating state of the scrubber is started after the amount of the impact gas is started to decrease.

7. The wafer processing apparatus according to claim 6,
wherein the scrubber needs a predetermined transition time from start of changing the operating state to completion of changing the operating state,
when the control device determines that an amount of the impact gas increases based on the processing condition, the control device transmits the scrubbing operation information for the scrubber immediately after obtaining the processing condition, and
when the control device determines that an amount of the impact gas decreases based on the processing condition, the control device transmits the scrubbing operation information for the scrubber after a second time earlier by the transition time that a first time at which the amount of the impact gas in the exhaust gas is started to decrease.

8. The wafer processing apparatus according to claim 1,
wherein the control device periodically obtains the processing condition, and
the control device compares the processing condition obtained at a given timing to the processing condition obtained immediately before the given timing to determine whether the amount of the impact gas increases or the amount of the impact gas decreases.

9. The wafer processing apparatus according to claim 2,
wherein the control device obtains the processing condition for the wafer processing unit from target time set arbitrarily in a predetermined period before the target time, and
the control device transmits the scrubbing operation information for the scrubber to change the operating state of the scrubber at the target time to enable the scrubbing process of the exhaust gas based on the processing condition obtained.

10. The wafer processing apparatus according to claim 2,
wherein the control device transmits the scrubbing operation information for the scrubber including an energy amount necessary for the scrubbing process based on the processing condition for the wafer processing unit.

11. The wafer processing apparatus according to claim 2,
wherein the scrubber needs a predetermined transition time from start of changing the operating state to completion of the change in the operating state.

12. The wafer processing apparatus according to claim 2,
wherein the control device obtains the processing condition for the wafer processing unit from target time arbitrarily set in a predetermined period before the target time,
when the control device determines that an amount of the impact gas at the target time increases based on based on the processing condition, the control device transmits the scrubbing operation information for the scrubber such that changing the operating state of the scrubber is completed before the amount of the impact gas is started to increases, and
when the control device determines that an amount of the impact gas at the target time decreases based on the processing condition, the control device transmits the scrubbing operation information for the scrubber such that changing the operating state of the scrubber is started after the amount of the impact gas is started to decrease.

13. The wafer processing apparatus according to claim 12,
wherein the scrubber needs a predetermined transition time from start of changing the operating state to completion of changing the operating state,
when the control device determines that an amount of the impact gas increases based on the processing condition, the control device transmits the scrubbing operation information for the scrubber immediately after obtaining the processing condition, and
when the control device determines that an amount of the impact gas decreases based on the processing condition, the control device transmits the scrubbing operation information for the scrubber after a second time earlier by the transition time that a first time at which the amount of the impact gas in the exhaust gas is started to decrease.

14. The wafer processing apparatus according to claim 2,
wherein the control device periodically obtains the processing condition, and
the control device compares the processing condition obtained at a given timing to the processing condition obtained immediately before the given timing to determine whether the amount of the impact gas increases or the amount of the impact gas decreases.
